(19) United States
(12) Patent Application Publication
(10) Pub. No.: US 2025/0331292 A1
(43) Pub. Date: Oct. 23, 2025

(54) BACKSIDE BALLAST RESISTOR

(71) Applicant: International Business Machines Corporation, Armonk, NY (US)

(72) Inventors: Gopal Sankar Kenath, Troy, NY (US); Tao Li, Slingerlands, NY (US); Ruilong Xie, Niskayuna, NY (US); Robert Gauthier, Williston, VT (US); Anindya Nath, Watervliet, NY (US)

(21) Appl. No.: 18/639,322

(22) Filed: Apr. 18, 2024

(51) Int. Cl. H01L 27/06; H01L 23/522; H01L 23/528; H01L 27/088; H01L 29/06; H01L 29/08; H01L 29/423; H01L 29/66; H01L 29/775; H01L 29/786

(52) U.S. Cl. CPC H10D 84/811; H01L 23/5228; H01L 23/528; H10D 30/014; H10D 30/43; H10D 30/6735; H10D 30/6757; H10D 62/121; H10D 62/151; H10D 64/017; H10D 84/83

(57) ABSTRACT

A semiconductor device is provided that includes a transistor located in a first device area and including a gate structure, a first source/drain region located on a first side of the gate structure and a second source/drain region located on a second side of the gate structure. The semiconductor device also includes a frontside source/drain contact structure contacting a topmost surface of the first source/drain region, a backside ballast resistor electrically contacting a bottommost surface of the second source/drain region, and a backside source/drain contact structure in contact with the backside ballast resistor.

### BACKGROUND

The present application relates to semiconductor technology, and more particularly to a semiconductor device including a backside ballast resistor.

A ballast resistor is defined as a resistor inserted into a circuit to uniformly distribute current. Ballast resistors also help to avoid over-current faults in a circuit. An “electric ballast” is a more general term used to refer to an electrical device used to maintain a circuit's stability by limiting the value of current and voltage. Electric ballasts can be resistors, capacitors, inductors, or a combination of these. Ballast resistors are able to change resistance with the current. If the current flowing through the resistor increases above the threshold value, the resistance increases. The resistance can then correspondingly decrease as the current decreases. In this way, the ballast resistor tries to maintain a constant current flowing through a circuit.

### SUMMARY

In one embodiment, a semiconductor device is provided that includes a transistor located in a first device area and including a gate structure, a first source/drain region located on a first side of the gate structure and a second source/drain region located on a second side of the gate structure. The semiconductor device also includes a frontside source/drain contact structure contacting a topmost surface of the first source/drain region, a backside ballast resistor electrically contacting a bottommost surface of the second source/drain region, and a backside source/drain contact structure in contact with the backside ballast resistor.

### BRIEF DESCRIPTION OF THE DRAWINGS

FIG. 1 is a cross sectional view illustrating a first exemplary structure located in a first device area of a substrate, and a second exemplary structure located in a second device area of the substrate that can be employed in accordance with an embodiment of the present application, each of the first exemplary structure and the second exemplary structure includes a nanosheet material stack of alternating sacrificial semiconductor material nanosheets and semiconductor channel material nanosheets, and a sacrificial gate structure located on top of the nanosheet material stack, and a block mask is also present protecting a portion of the sacrificial gate structure that is present in the first device area.

FIG. 2 is a cross sectional view illustrating the exemplary first exemplary structure and second exemplary structure shown in FIG. 1 after forming a backside source/drain contact placeholder structure in both the first device area and the second device area.

FIG. 3 is a cross sectional view illustrating the exemplary first exemplary structure and second exemplary structure shown in FIG. 2 after nanosheet transistor formation and frontside processing.

FIG. 4 is a cross sectional view illustrating the exemplary first exemplary structure and second exemplary structure shown in FIG. 3 after flipping the substrate, and removing a semiconductor base layer of the substrate to physically expose an etch stop layer of the substrate.

FIG. 5 is a cross sectional view illustrating the exemplary first exemplary structure and second exemplary structure shown in FIG. 4 after removing the physically exposed etch stop layer and a semiconductor device layer of the substrate to reveal the backside source/drain contact placeholder structure in both the first device area and the second device area.

FIG. 6 is a cross sectional view illustrating the exemplary first exemplary structure and second exemplary structure shown in FIG. 5 after forming a backside interlayer dielectric (ILD) layer embedding the revealed backside source/drain contact placeholder structure that is present in both the first device area and the second device area.

FIG. 7 is a cross sectional view illustrating the exemplary first exemplary structure and second exemplary structure shown in FIG. 6 after backside ballast resistor patterning of the backside ILD layer to reveal the backside source/drain contact placeholder structure that is present in the first device area.

FIG. 8 is a cross sectional view illustrating the exemplary first exemplary structure and second exemplary structure shown in FIG. 7 after removing the revealed backside source/drain contact placeholder structure that is present in the first device area.

FIG. 9 is a cross sectional view illustrating the exemplary first exemplary structure and second exemplary structure shown in FIG. 8 after forming a ballast resistor in the first device area that is in contact (indirectly or directly) with a source/drain region of the nanosheet transistor that is present in the first device area.

FIG. 10 is a cross sectional view illustrating the exemplary first exemplary structure and second exemplary structure shown in FIG. 9 after backside source/drain contact patterning.

FIG. 11 is a cross sectional view illustrating the exemplary first exemplary structure and second exemplary structure shown in FIG. 10 after removing the backside source/drain contact mask that was used for backside source/drain contact patterning, and removing the reveled backside source/drain contact placeholder structure that is present in the second device area.

FIG. 12 is a cross sectional view illustrating the exemplary first exemplary structure and second exemplary structure shown in FIG. 11 after forming backside source/drain contact structures in both the first device area and the second device area, and forming a backside interconnect structure.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. In the embodiment described in the present application, the transistor is a nanosheet transistor. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology. Although nanosheet transistors are described in this application, this application is not limited to nanosheet transistors. Instead, the present application can be used for finFETs, nanowire FETs, planar FETs, fork sheet transistors, stacked FETs or any combination of such FETs including nanosheet transistors.

In the present application, the semiconductor device includes a frontside and a backside. The frontside includes a side of the device that includes at least one transistor, frontside contact structures, and a frontside BEOL structure. The backside of the semiconductor device is the side of the device that is opposite the frontside. The backside includes backside contact structures, and a backside interconnect structure. The backside interconnect structure can be a backside power distribution network that is capable of delivering power to the transistor through the backside of the semiconductor device.

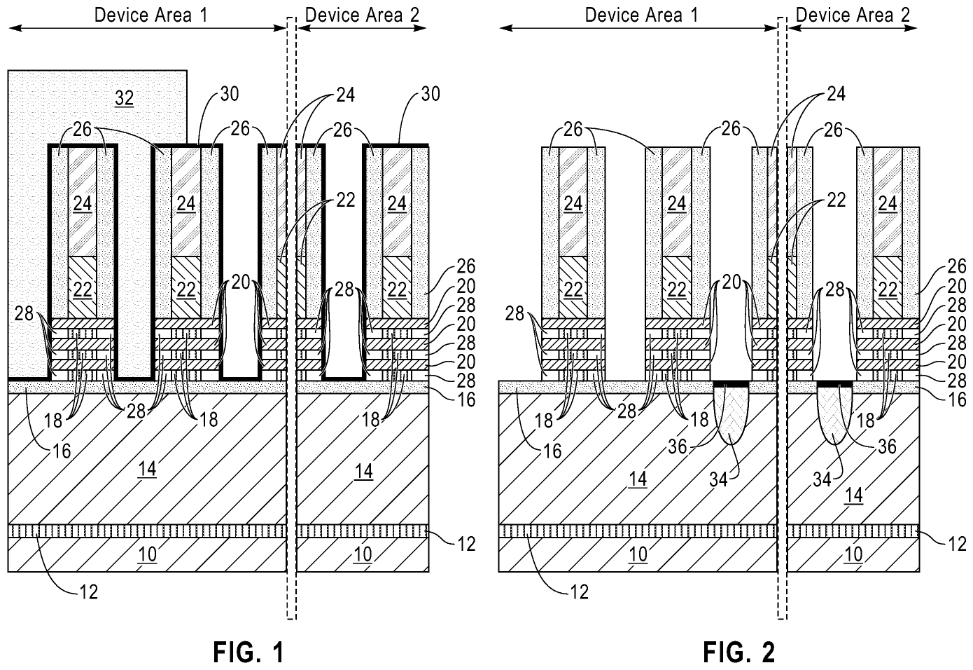

Reference is first made to FIG. 1, which illustrates a first exemplary structure located in a first device area, i.e., Device Area 1, as shown in FIG. 1, of a substrate and a second exemplary structure located in a second device area, i.e., Device Area 2, as shown in FIG. 1, of the substrate that can be employed in accordance with an embodiment of the present application. In some embodiments, the second device area can be omitted and only the first device area is present. In the present application, the first device area represents an area in which a semiconductor device including a backside ballasting resistor will be subsequently formed, while the second device area is an area in which a logic device will be subsequently formed.

Each of the first exemplary structure and the second exemplary structure includes a nanosheet material stack of alternating sacrificial semiconductor material nanosheets 18 and semiconductor channel material nanosheets 20, and a sacrificial gate structure 22 located on top of the nanosheet material stack. As is shown in FIG. 1, a block mask 32 is present protecting a portion of the sacrificial gate structure 22 that is present in the first device area; other sacrificial gate structures 22 present in the first device area can be completely protected by the block mask 32.

The substrate includes a semiconductor base layer 10, an etch stop layer 12, and a semiconductor device layer 14. Embodiments are contemplated in which the semiconductor base layer 10 and/or the etch stop layer 12 are omitted and the substrate includes only the semiconductor device layer 14. In some embodiments of the present application, a bottom dielectric isolation layer 16 can be present on a surface of the semiconductor device layer 14. When present, the bottom dielectric isolation layer 16 is present beneath the nanosheet material stacks that are present in both the first device area and the second device area. The first exemplary structure and the second exemplary structure shown in FIG. 1 can further include a sacrificial gate cap 24 located on each sacrificial gate structure 22, a gate spacer 26 located along a sidewall of each sacrificial gate structure 22 and, if present, each sacrificial gate cap 24, and an inner spacer 28 located at the ends of each of the sacrificial semiconductor material nanosheets 18. Also present, is a sacrificial dielectric liner 30 that is present on physically exposed surfaces of the gate spacer 26, the inner spacer 28 and the ends of each of the semiconductor channel material nanosheets 20. The sacrificial dielectric liner 30 is used to protect the semiconductor channel material nanosheets 20 during the subsequent formation of a backside source/drain contact placeholder structure 34, as is illustrated in FIG. 2.

The base semiconductor layer 10 is composed of a first semiconductor material, and the semiconductor device layer 14 is composed of a second semiconductor material. The term “semiconductor material” is used throughout the present application to denote a material having semiconducting properties. Examples of semiconductor materials that can be used in the present application in providing the first semiconductor material and the second semiconductor material include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the semiconductor base layer 14 can be compositionally the same as, or compositionally different from, the first semiconductor material that provides the semiconductor base layer 10.

In some embodiments of the present application, the etch stop layer 12 can be composed of a dielectric material such as, for example, silicon dioxide and/or boron nitride. In other embodiments of the present application, the etch stop layer 12 is composed of a third semiconductor material that is compositionally different from the first semiconductor material that provides the semiconductor base layer 10 and the second semiconductor material that provides the semiconductor device layer 14. In one example, the semiconductor base layer 10 is composed of silicon, the etch stop layer 12 is composed of silicon dioxide, and the semiconductor device layer 14 is composed of silicon. In another example, the semiconductor base layer 10 is composed of silicon, the etch stop layer 12 is composed of silicon germanium, and the semiconductor device layer 14 is composed of silicon.

The substrate including the semiconductor base layer 10, the etch stop layer 12 and the semiconductor device layer 14 can be formed utilizing techniques well known to those skilled in the art. For example, the substrate including the semiconductor base layer 10, the etch stop layer 12 and the semiconductor device layer 14 can be formed by a separation by ion implantation of oxygen process, or wafer bonding. Alternatively, the substrate including the semiconductor base layer 10, the etch stop layer 12 and the semiconductor device layer 14 can be formed by deposition of the various substrate layers one on top the other. The deposition used in forming the various substrate layers can include, but is not limited to, chemical vapor deposition (CVD), plasma enhanced chemical vapor deposition (PECVD), or epitaxial growth. The terms “epitaxial growth” or “epitaxially growing” means the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C. Although higher temperature typically results in faster deposition, the faster deposition may result in crystal defects and film cracking.

As mentioned above, each nanosheet material stack includes alternating sacrificial semiconductor material nanosheets 18 and semiconductor channel material nanosheets 20. In some embodiments and as is illustrated in FIG. 1, each nanosheet material stack can include ‘n’ number of sacrificial semiconductor material nanosheets 18 and “n” number of semiconductor channel material nanosheets 20, where n is an integer starting at 1, typically n is greater than 1. By way of one example, each nanosheet material stack can include three sacrificial semiconductor material nanosheets 18 and three semiconductor channel material nanosheets 20. Although not illustrated, each nanosheet material stack can include “m” number of semiconductor channel material nanosheets 20 and “m+1” number of sacrificial semiconductor material nanosheets 18, wherein m is an integer greater than one. In the non-illustrated embodiment, each semiconductor channel material nanosheet 20 would be sandwiched between a bottom sacrificial semiconductor material nanosheet and a top sacrificial semiconductor material nanosheet.

Each sacrificial semiconductor material nanosheet 18 is composed of a fourth semiconductor material, while each semiconductor channel material nanosheet 20 is composed of a fifth semiconductor material that is compositionally different from the fourth semiconductor material. In some embodiments, the fifth semiconductor material that provides each semiconductor channel material nanosheet 20 can provide high channel mobility for n-type FET devices (i.e., NFETs). In other embodiments, the fifth semiconductor material that provides each semiconductor channel material nanosheet 20 can provide high channel mobility for p-type FET devices (PFETs). The fourth semiconductor material that provides each sacrificial semiconductor material nanosheet 18, and the fifth semiconductor material that provides each semiconductor channel material nanosheet 20 can include one of the semiconductor materials mentioned above. In one example, the fourth semiconductor material that provides each sacrificial semiconductor material nanosheet 18 is composed of a silicon germanium alloy having a germanium content from 20 atomic percent to 40 atomic percent and the fifth semiconductor material that provides each semiconductor channel material nanosheet 20 is composed of silicon. Other combinations of semiconductor materials are possible as long as the fourth semiconductor material that provides each sacrificial semiconductor material nanosheet 18 is compositionally different from the fifth semiconductor material that provides each semiconductor channel material nanosheet 20.

The gate spacer 26, the inner spacer 28 and the bottom dielectric isolation layer 16 are each composed of a spacer dielectric material. In present application, the gate spacer 26 and the bottom dielectric isolation layer 16 are typically composed of a same spacer dielectric material since both the gate spacer 26 and the bottom dielectric isolation layer 16 are generally formed at the same time. Illustrative examples spacer dielectric materials that can be used in providing the gate spacer 26, the inner spacer 28 and the bottom dielectric isolation layer 16 include, but are not limited to, silicon dioxide, silicon nitride, SiBCN, CiOCN or SiOC.

Each sacrificial gate structure 22 includes at least a sacrificial gate material. In some embodiments, each sacrificial gate structure 22 can also include a sacrificial gate dielectric material. In such embodiments, the sacrificial gate dielectric material would be located beneath the sacrificial gate material. The optional sacrificial gate dielectric material can be composed of a dielectric material such as, for example, silicon dioxide. The sacrificial gate material can be composed of, for example, polysilicon, amorphous silicon, amorphous silicon germanium or amorphous germanium.

When present, the sacrificial gate cap 24 is composed of a dielectric hard mask material such as, for example, silicon dioxide, silicon nitride and/or silicon oxynitride. The sacrificial dielectric liner 30 is composed of a dielectric material such as, for example, silicon dioxide or silicon nitride. The sacrificial dielectric liner 30 is typically, but necessarily always, a conformal layer. The term “conformal” denotes that a layer has a same thickness as measured from a horizontal surface of another layer as a thickness as measured from a vertical surface of the another layer. The block mask 32 is composed of a block mask material including, for example, an organic planarization material.

The first and second exemplary structures illustrated in FIG. 1 can be formed utilizing nanosheet formation processes that are well known to those skilled in the art, followed by formation of the sacrificial dielectric liner 30, and then the block mask 32. The nanosheet formation processes can include, for example, various deposition and patterning steps. The depositions can include, but are not limited, chemical vapor deposition (CVD), plasma enhanced chemical vapor deposition (PECVD), physical vapor deposition (PVD), and atomic layer deposition (ALD). In some embodiments, an epitaxial growth process can be used to form blanket layers of the fourth and fifth semiconductor materials that provide the sacrificial semiconductor material nanosheets 18 and the semiconductor channel material nanosheets respectively. The sacrificial gate structure 22 and, if present, the sacrificial gate cap 24 can then be formed by deposition of a blanket layer of at least the at least a sacrificial gate material, followed by deposition of a blanket layer of a hard mask material. The blanket layer of at least the at least a sacrificial gate material and the blanket layer of a hard mask material are then patterned to form the sacrificial gate structure 22 and a sacrificial gate cap 24, respectively. Patterning can include lithography and etching (dry etching and/or chemical wet etching). Dry etching can include, for example, reactive ion etching (RIE), ion beam etching (IBE), and plasma etching. Chemical wet etching includes the use of an appropriate chemical etchant that has a high etch rate for one material as compared to at least one another material. Gate spacer 26 is then formed by deposition of at least one of the spacer dielectric materials mentioned above, followed by a spacer etch. In some embodiments, the bottom dielectric isolation layer 16 is formed at the same time as the gate spacer 26. In such embodiments, a sacrificial semiconductor layer is present on the semiconductor device layer 14, and after formation of the sacrificial gate structure 22, the sacrificial semiconductor layer is removed, and then a spacer dielectric material is deposited to provide both the bottom dielectric isolation layer 16 and the gate spacer 26. The blanket layers of the fourth and fifth semiconductor materials can then be patterned by a nanosheet etch in which the sacrificial gate structure 22 and the gate spacer 26 are used as a combined etch mask. The patterning of the blanket layers of the fourth and fifth semiconductor materials provides the nanosheet material stacks illustrated in FIG. 1. Next, inner spacer 28 is formed by first indenting (via a recess etching process) each sacrificial semiconductor material nanosheet 18, then depositing one of the above dielectric spacer materials in the gap created by the indenting, and thereafter removing any deposited dielectric spacer material that is formed outside of the gap. The sacrificial dielectric liner 30 is then formed by a deposition process such as, for example, CVD, PECVD or ALD, and then the block mask 32 is formed by deposition of a block material, followed by lithographic patterning of the as-deposited block mask material.

Referring now to FIG. 2, there is illustrated the exemplary first exemplary structure and second exemplary structure shown in FIG. 1 after forming a backside source/drain contact placeholder structure 34 in both the first device area, and the second device area. The backside source/drain contact placeholder structure 34 is formed by first punching through the sacrificial dielectric liner 30 and the bottom dielectric isolation layer 16 that is located adjacent to each side of the sacrificial gate structure 22. The dielectric punch through can stop on a topmost surface of the semiconductor device layer 14. The dielectric punch through includes an etching process that is selective in removing the physically exposed portion of the sacrificial dielectric liner 30 and the bottom dielectric isolation layer 16 that is located adjacent to each side of the sacrificial gate structure 22. After dielectric punch through, a backside source/drain contact placeholder cavity is formed into the semiconductor device layer 14 of the substrate utilizing an etch that is selective in removing a portion of the semiconductor device layer 14. After formation of the backside source/drain contact placeholder cavity, the block mask 32 can be removed utilizing a material removal process such as, for example, ashing, which is selective in removing the block mask 32; this typically occurs prior to filling the cavity. The remaining sacrificial dielectric liner 30 can be removed utilizing another material removal process that is selective in removing the dielectric liner; the removal of the remaining dielectric liner 30 can occur prior to, or after, filling the cavity. The backside source/drain contact placeholder cavity is then filled with a sixth semiconductor material which is compositionally different from the second semiconductor material that provides the semiconductor device layer 14. In one example, sixth semiconductor material is a silicon germanium alloy. The sixth semiconductor material can be formed by deposition (e.g., CVD, PECVD or epitaxial growth) and then a recess etch can be used to remove any sixth semiconductor material that is formed outside of the backside source/drain contact placeholder cavity providing backside source/drain contact placeholder structure 34 as shown in FIG. 2. Note that the backside source/drain contact placeholder structure 34 can extend above the topmost surface of the semiconductor device layer 14, but the height of the backside source/drain contact placeholder structure 34 is typically less than, or equal to, a topmost surface of the bottom dielectric isolation layer 16.

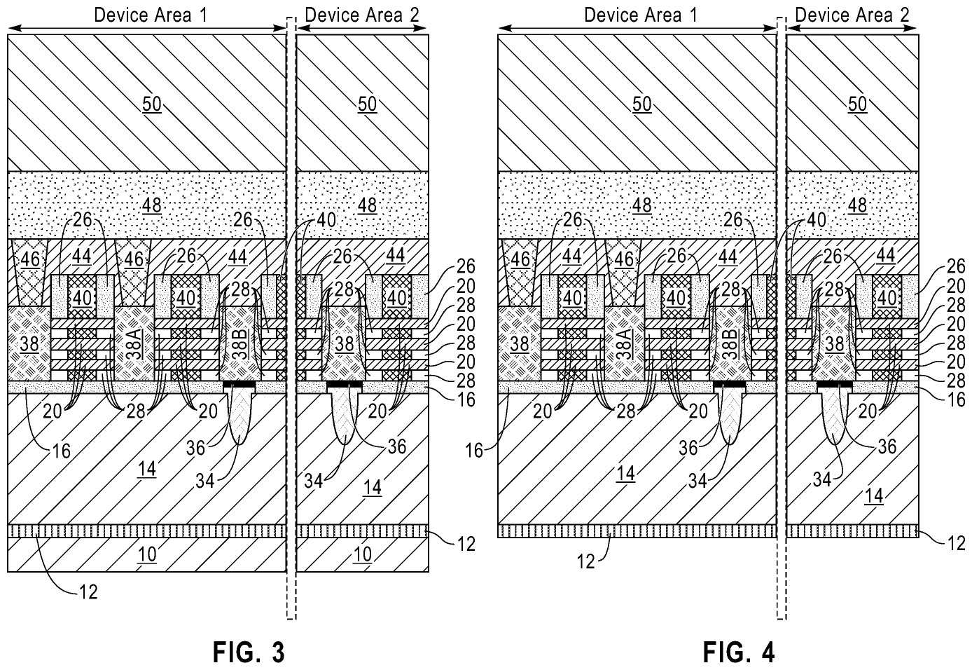

In some embodiments of the present application and as is illustrated in FIG. 2, a semiconductor layer 36 can be formed on top of the source/drain contact placeholder structure 34. In other embodiments, the semiconductor layer 36 can be omitted. The semiconductor layer 36 is composed of a seventh semiconductor material that can be compositionally different from the sixth semiconductor material that provides the backside source/drain contact placeholder structure 34. The semiconductor layer 36 can be formed by deposition (e.g., CVD, PECVD or epitaxial growth), followed by a recess etch. The semiconductor layer 36 can be used as a growth surface for the subsequent formation of source/drain regions 38 as shown in FIG. 3. Note that the semiconductor layer 36 can have a topmost surface that is substantially coplanar with the topmost surface of the bottom dielectric isolation layer 16, but the height of the backside source/drain contact placeholder structure 34 is typically less than a topmost surface of the bottommost semiconductor channel material nanosheet 20.

Referring now to FIG. 3, there is illustrated the exemplary first exemplary structure and second exemplary structure shown in FIG. 2 after nanosheet transistor formation and frontside processing. The nanosheet transistor formation includes forming source/drain regions 38 on each side of the sacrificial gate structure 22. In the present application and for one of the transistors present in the first device area, one of source/drain regions 38 is formed on a surface of the bottom dielectric isolation layer 16 and the other source/drain region 38 is formed either on a surface of the semiconductor layer 36 (if the present), or on a surface of the backside source/drain contact placeholder structure 34 if the semiconductor layer 36 is not present. In the present application, the source/drain region that is formed on the bottom dielectric isolation layer 16 is a first source/drain region 38A of the transistor and the source/drain region that is formed on either the semiconductor layer 36 or the backside source/drain contact placeholder structure 34 is a second source/drain region 38B of the same transistor. Notably, and in the drawings, the first source/drain region 38A is on the left hand side of the second gate structure shown in the first device area and the second source/drain region 38B is on the right hand side of this second gate structure. The source/drain regions 38 (including the first source/drain region 38A and the second source/drain region 38B) are formed outward from the ends of each semiconductor channel material nanosheet 20. The source/drain regions 38 (including the first source/drain region 38A and the second source/drain region 38B) are typically formed by an epitaxial growth process, as defined above. A recess etch can follow the epitaxial growth process. The source/drain regions 38 (including the first source/drain region 38A and the second source/drain region 38B) are composed of an eighth semiconductor material and a first dopant. The eighth semiconductor material can be compositionally the same as, or compositionally different from the fifth semiconductor material that provides each semiconductor channel material nanosheet 20. The first dopant that is present in the source/drain region 38 (including the first source/drain region 38A and the second source/drain region 38B) can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, the source/drain regions 38 (including the first source/drain region 38A and the second source/drain region 38B) can have a dopant concentration of from 4×10²⁰ atoms/cm³ to 3×10²¹ atoms/cm³.

After forming the source/drain regions 38 (including the first source/drain region 38A and the second source/drain region 38B), a first frontside interlayer dielectric (ILD) layer (not specifically shown in FIG. 3) is formed on physically exposed surfaces of the source/drain regions 38 (including the first source/drain region 38A and the second source/drain region 38B). The first frontside ILD layer is composed of a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0 (all dielectric constants mentioned herein are relative to a vacuum unless otherwise noted). The frontside ILD layer can be formed by a deposition process including, but not limited to, CVD, PECVD or spin-on coating. A planarization process such as, for example, chemical mechanical polishing (CMP) follows the deposition process. The planarization process can remove each sacrificial gate cap 24 and an upper portion of each gate spacer 26 and reveal a topmost surface of each sacrificial gate structure 22. The reveled sacrificial gate structure 22 can then be removed utilizing a material removal process such as, for example, RIE, to physically expose each nanosheet material stack. Each of the sacrificial semiconductor material nanosheets 18 is then removed by a material removal process that is selective in removing the sacrificial semiconductor material nanosheets 18. The removal of the sacrificial semiconductor material nanosheets 18 suspends a portion of each of the semiconductor channel material nanosheets 20 of the original nanosheet material stacks.

Gate structure 40 is then formed around the suspended portion of each of the semiconductor channel material nanosheets 20. Gate structure 40 includes a gate dielectric material and a gate electrode, both of which are not separately shown, but intended to be within region defined by the gate structure 40. As is known to those skilled in the art, the gate dielectric material directly contacts a physically exposed surface(s) of the semiconductor channel region (e.g., each semiconductor channel material nanosheet 20), and the gate electrode is formed on the gate dielectric material. The gate dielectric material has a dielectric constant of 4.0 or greater. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg). The gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co). The gate structure 40 can be formed by deposition of the gate dielectric material, and gate electrode material, followed by a planarization process. At this point of the present application, the gate structure 40 has a topmost surface that is coplanar with a topmost surface of the frontside ILD layer. This completes the formation of the nanosheet transistors in the first device area and the second device area. Note that the gate structures 40 formed in the first device area can be compositionally the same as, or compositionally different from, the gate structure 40 that is formed in the second device area; gate structures of different composition can be obtained by utilizing block mask technology to block one of the device areas while other of the device areas is processed to include a first gate structure. The block mask can be removed, and thereafter another block mask can be formed in the device area including the first gate structure, and then a second gate structure is formed in the other device area.

After forming the gate structure 40, frontside processing is performed. The frontside processing includes forming an additional frontside ILD material on the first frontside ILD layer and atop each of the gate structures 40. In the present application, the additional frontside ILD layer and the frontside ILD layer collectively provide a middle-of-the-line (MOL) dielectric layer 44. The additional frontside ILD layer can be composed of a dielectric material that is compositionally the same as, or compositionally different from, the dielectric material that provides the frontside ILD layer. Typically, the dielectric material that provides the additional ILD layer is compositionally the same as the dielectric material that provides the frontside ILD layer such that within the MOL dielectric layer 44 no material interface would exist between the additional frontside ILD layer and the frontside ILD layer; such an embodiment is shown in the drawings of the present application. When compositionally different dielectric materials are employed for the additional frontside ILD layer and the frontside ILD layer, the MOL dielectric layer 44 would contain a material interface between the two compositionally different dielectric materials. Such an embodiment is not however shown in the drawings of the present application. The additional frontside ILD layer can be formed utilizing one of the deposition processes mentioned above in forming the frontside ILD layer.

Frontside contact structures including a frontside source/drain contact structure 46 and typically a frontside gate contact structure (not shown for clarity) are then formed utilizing a metallization process that includes forming frontside contact openings in the MOL dielectric layer 44, and thereafter filling (including deposition and planarization) each frontside contact opening with at least a contact conductor material. The contact conductor material can include, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. The frontside contact structures can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above. The frontside source/drain contact structure 46 contacts the first source/drain region 38A that is present on the bottom dielectric isolation layer 16. Each frontside contact structure (including the frontside source/drain contact structure 46) has a topmost surface that is substantially coplanar with a topmost surface of the MOL dielectric layer 44. The frontside source/drain contact structure 46, the frontside gate contact structure and MOL dielectric layer 44 represent a MOL level that is located on a frontside of the illustrated structures shown in FIG. 3.

Frontside back-end-of-the-line (BEOL) structure 48 is then formed on the MOL level. In the illustrated embodiment, the frontside BEOL structure 48 is electrically connected to the first source/drain region (i.e., the source/drain region that is located on the bottom dielectric isolation layer 16) of the gate structure 40 by frontside source/drain contact structure 46. The frontside BEOL structure 46 can include one or more interconnect dielectric material layers (including one of the dielectric materials mentioned above for the frontside ILD layer) that contain frontside metal wires (the metal wires can be composed of any electrically conductive metal or electrically conductive metal alloy) embedded therein. The frontside BEOL structure 48 can include “x” numbers of frontside metal levels, wherein “x” is an integer starting from 1. The frontside BEOL structure 48 can be formed utilizing techniques well known to those skilled in the art. In some embodiments, the frontside metal wires in the frontside BEOL structure 48 are composed of Cu.

A carrier wafer 50 is then typically formed on the frontside BEOL structure 48. The carrier wafer 50 can include one of the first semiconductor materials mentioned above for the semiconductor base layer 10. Carrier wafer 50 is bonded to the frontside BEOL structure 48 after frontside BEOL structure 48 formation. The carrier wafer 50 is typically removed from the structure after backside processing of the structure is completed. Frontside processing has now be completed and the exemplary structures shown in each of the device areas are ready for backside processing.

Referring now to FIG. 4, there is illustrated the exemplary first exemplary structure and second exemplary structure shown in FIG. 3 after flipping the substrate, and removing the semiconductor base layer 10 of the substrate to physically expose the etch stop layer 12 of the substrate. In the present application, the structures shown in FIG. 4 are flipped 180° to physically expose a backside of the substate. This flipping step is not shown in the drawings of the present application for clarity. This flipping step will allow backside processing of the exemplary first and second structures. Backside processing occurs on a side of a substrate (or wafer) opposite the side where the transistors have been formed; in the present application the backside of the substrate can be defined as the area of the substrate that is beneath the bottom dielectric isolation layer 16. Flipping of the structure can be performed by hand or by utilizing a mechanical means such as, for example, a robot arm. The removal of the physically exposed semiconductor base layer 10 can be performed utilizing a material removal process that is selective in removing the first semiconductor material that provides the semiconductor base layer 10.

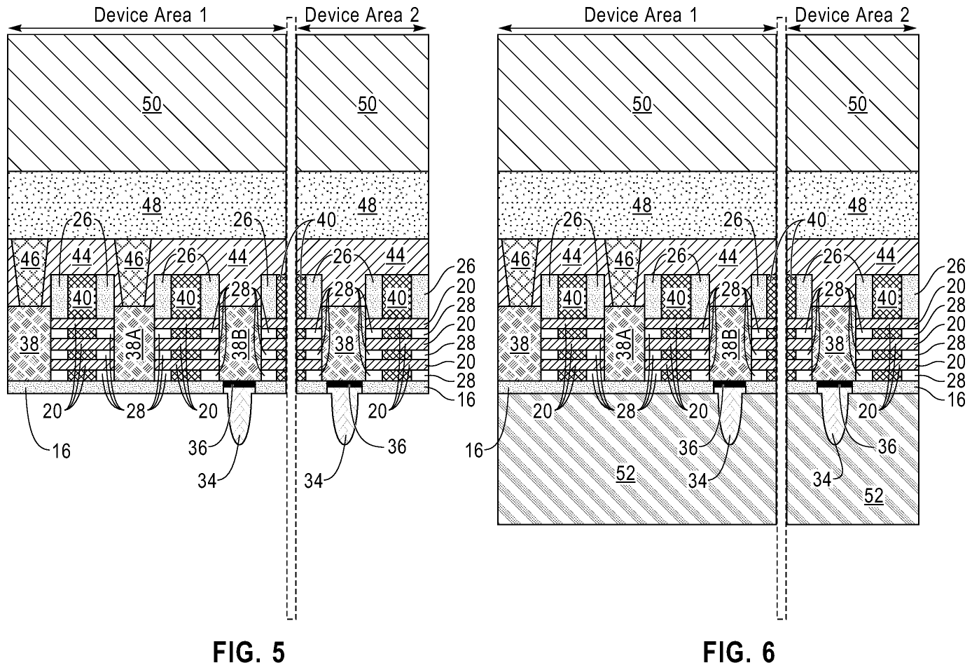

Referring now to FIG. 5, there is illustrated the exemplary first exemplary structure and second exemplary structure shown in FIG. 4 after removing the physically exposed etch stop layer 12 and the semiconductor device layer 14 of the substrate to reveal the backside source/drain contact placeholder structure 34 in both the first device area and the second device area. The removal of the etch stop layer 12 can be performed utilizing a material removal process that is selective in removing the etch stop layer 12. The removal of the semiconductor device layer 14 can be performed utilizing a material removal process that is selective in removing second semiconductor material that provides the semiconductor device layer 14. In some embodiments, an entirety of the semiconductor device layer 14 is removed as is shown in FIG. 5. In other embodiments, a portion of the semiconductor device layer 14 is removed, while maintaining a thin portion of the semiconductor device layer 14 on the bottom dielectric isolation layer 16.

Referring now to FIG. 6, there is illustrated the exemplary first exemplary structure and second exemplary structure shown in FIG. 5 after forming a backside ILD layer 52 embedding the revealed backside source/drain contact placeholder structure 34 that is present in both the first device area and the second device area. The backside ILD layer 52 is composed of one of the dielectric materials mentioned above for the first frontside ILD layer. The backside ILD layer 52 can be formed by a deposition process including those mentioned above in forming the first frontside ILD layer. A planarization process can follow the deposition of the dielectric material that provides the backside ILD layer 52. In the illustrated embodiment, the backside ILD layer 52 forms an interface with the physically exposed bottommost surface of the bottom dielectric isolation layer 16.

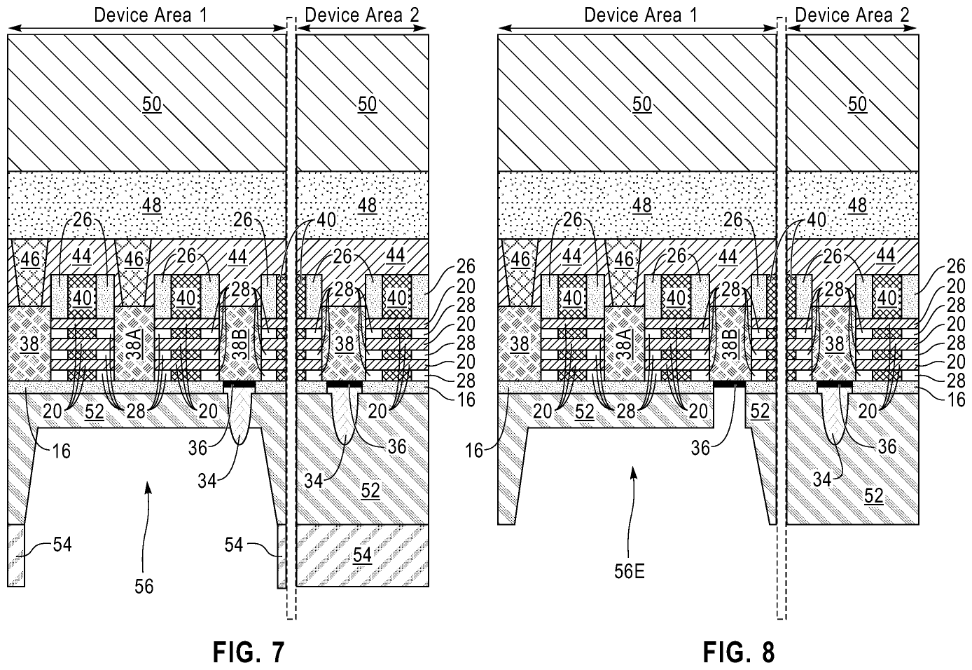

Referring now to FIG. 7, there is illustrated the exemplary first exemplary structure and second exemplary structure shown in FIG. 6 after backside ballast resistor patterning of the backside ILD layer 36 to reveal the backside source/drain contact placeholder structure 34 that is present in the first device area; the backside source/drain contact placeholder structure 34 that is present in the second device area is not revealed during the backside ballast resistor patterning process. The backside ballast resistor patterning process includes forming a backside ballast resistor patterned mask 54 having an opening on the backside ILD layer 52. The backside ballast resistor patterned mask 54 can include any masking material including, for example, an organic planarization material, or a combination of masking materials, and it can be formed by deposition of the masking material or a combination of masking materials, followed by lithography and etching. With the backside ballast resistor patterned mask 54 in place, an etch is then employed through the opening to remove a portion of backside ILD layer 52 that is not protected by the backside ballast resistor patterned mask 54. First opening 56 is formed in the backside ILD layer 52 that is present in the first device area which physically exposes a lower portion of the backside source/drain contact placeholder structure 34 that is present in the first device area.

Referring now to FIG. 8, there is illustrated the exemplary first exemplary structure and second exemplary structure shown in FIG. 7 after removing the revealed backside source/drain contact placeholder structure 34 that is present in the first device area. The removal of the revealed backside source/drain contact placeholder structure 34 that is present in the first device area includes an etch that is selective in removing the revealed backside source/drain contact placeholder structure 34 that is present in the first device area. The removal of the revealed backside source/drain contact placeholder structure 34 provides extended first opening 56E in the first device area. Prior to the removal of the revealed backside source/drain contact placeholder structure 34, the backside ballast resistor patterned mask 54 is removed utilizing a material removal process such as, for example, ashing, which is selective in removing the backside ballast resistor patterned mask 54.

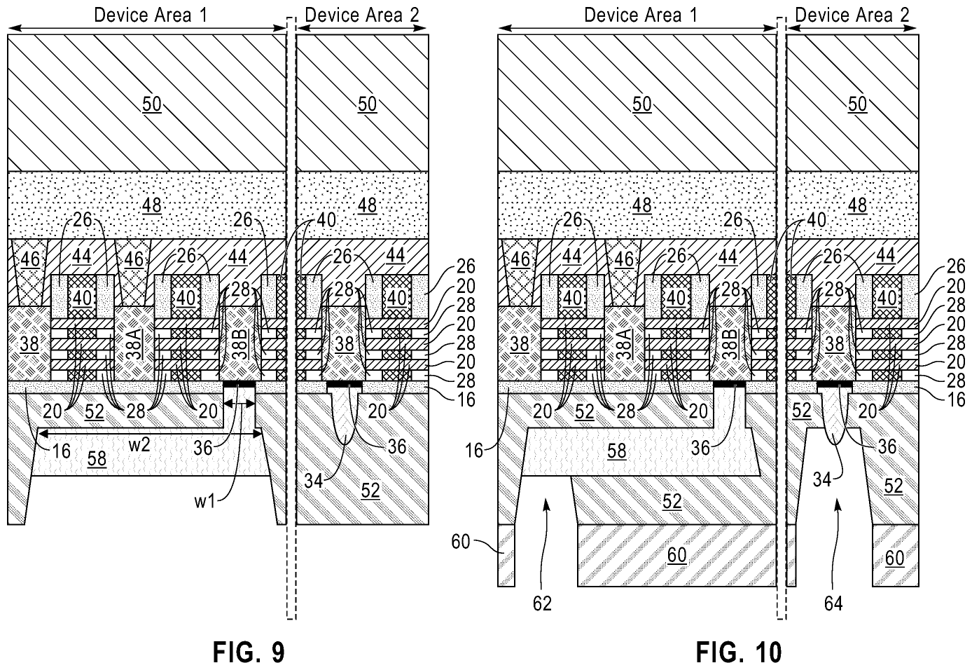

Referring now to FIG. 9, there is illustrated the exemplary first exemplary structure and second exemplary structure shown in FIG. 8 after forming a backside ballast resistor 58 in the first device area that is in contact (indirectly or directly) with the second source/drain region 38B of the nanosheet transistor that is present in the first device area. In the present application, the backside ballast resistor 58 is in contact (indirectly or directly) with the second source/drain region 38B; the first source/drain region 38A is in electrical contact with the frontside source/drain contact structure 46. The backside ballast resistor 58 is composed of a ninth semiconductor material and a second dopant that is of a same conductivity type as the first dopant present in the second source/drain region 38B. Thus, and in the present application, the second source/drain region 38B and the backside ballast resistor 58 are of same conductivity type. In some embodiments, the backside ballast resistor 58 and the second source/drain region 38B have an n-type conductivity. In other embodiments, the backside ballast resistor 58 and the second source/drain regions 38B have a p-type conductivity. The ninth semiconductor material that provides the backside ballast resistor 58 can be compositionally the same as, or compositionally different from the eighth semiconductor material than provides the source/drain regions 38 (including the first and second source/drain regions mentioned herein). The ninth semiconductor material that provides the backside ballast resistor 58 however is compositionally different from the sixth semiconductor material that provides the backside source/drain contact placeholder structure 34. The backside ballast resistor 58 is typically formed utilizing an epitaxial growth process in which the second dopant is introduced during the epitaxial growth process itself. Ballasting resistance is key in electrostatic detection (ESD) devices to spread the current in one finger and across many fingers. Typical ESD devices have many small fingers (unit cells) to make up one large structure so having all fingers turned on in parallel is key to handling high current ESD events. The backside ballast resistor 58 performs such ballasting.

In some embodiments of the present application and as is shown in FIG. 9, the backside ballast resistor 58 is spaced apart from the second source/drain region 38B by the semiconductor layer 36. In such embodiments, the backside ballast resistor 58 is in direct physical contact with the semiconductor layer 36. In other embodiments of the present application (not illustrated but obvious from FIG. 9), the backside ballast resistor 58 is in direct physically contact with a bottommost surface of the second source/drain region 38B. As is illustrated in FIG. 9, the backside ballast resistor 58 has an upper portion having a first width, w1, and a lower portion having a second width, w2, in which the second width, w2, is greater than the first width, w1. In the present application, w1 is used to make a vertical resistance connection to the second source/drain region 38B.
The second width, w2, is the bulk of the ballasting resistance and the larger w2 is the more squares of ballasting resistance is achieved leading to a larger overall resistance, this resistance value tuning using w2 is critical to fine tune to optimize the ESD device current spreading. After forming the backside ballast resistor 58, additional backside ILD material having a same composition as that of the backside ILD layer 52 can be formed to fill in a remaining portion of the first extended opening 56E.

Referring now to FIG. 10, there is illustrated the exemplary first exemplary structure and second exemplary structure shown in FIG. 9 after backside source/drain contact patterning. The backside source/drain contact patterning process includes forming a backside source/drain contact mask 60 having a first opening in the first device area and a second opening in the second device area, both the first and second openings in the backside source/drain contact mask 60 physically exposing a surface of the backside ILD layer 52. The backside source/drain contact mask 60 can include any masking material including, for example, an organic planarization material, or a combination of masking materials, and it can be formed by deposition of the masking material or a combination of masking materials, followed by lithography and etching. With the backside source/drain contact mask 60 in place, an etch is then employed through the two openings in the backside source/drain contact mask 60 to remove a portion of backside ILD layer 52 that is not protected by the backside source/drain contact mask 60. First source/drain contact opening 62 is formed in the backside ILD layer 52 that is present in the first device area, and second source/drain contact opening 64 is formed in the second device area. The second source/drain contact opening 64 reveals a lower portion of the backside source/drain contact placeholder structure 34 that is present in the second device area.

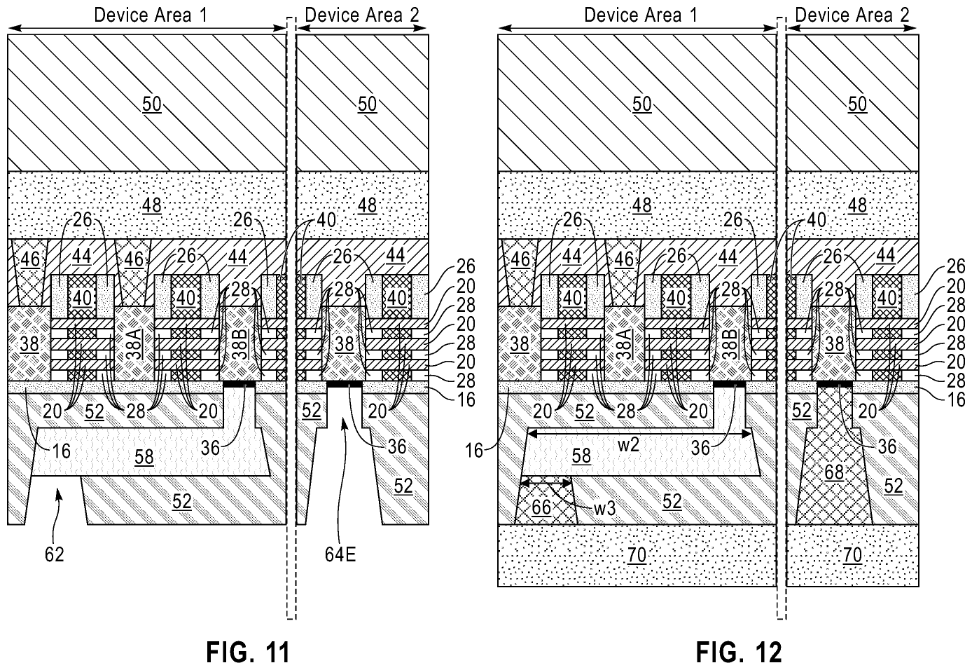

Referring now to FIG. 11, there is illustrated the exemplary first exemplary structure and second exemplary structure shown in FIG. 10 after removing the backside source/drain contact mask 60 that was used for backside source/drain contact patterning, and removing the reveled backside source/drain contact placeholder structure 34 that is present in the second device area. The backside source/drain contact mask 60 can be removed utilizing a material removal process such, as for example, ashing, which is selective in removing the backside source/drain contact mask 60. The reveled backside source/drain contact placeholder structure 34 that is present in the second device area can be removed utilizing a material removal process that is selective in removing the reveled backside source/drain contact placeholder structure 34. An extended second source/drain contact opening 64E is formed as shown in FIG. 11.

Referring now to FIG. 12, there is illustrated the exemplary first exemplary structure and second exemplary structure shown in FIG. 11 after forming backside source/drain contact structures in both the first device area and the second device area, and forming a backside interconnect structure 70. Notably, a first backside source/drain contact structure 66 is formed in the first source/drain contact opening 62 that is in direct contact with the backside ballast resistor 58, and a second backside source/drain contact structure 68 is formed in the extended second source/drain contact opening 64E that is in contact (indirectly or directly) with one of the source/drain regions 38 of the nanosheet transistor that is present in the second device area.

The first backside source/drain contact structure 66 and the second backside source/drain contact structure 68 are composed of a contact conductor material, as defined above. The contact conductor material can include, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. The first backside source/drain contact structure 66 and the second backside source/drain contact structure 68 can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above. The first backside source/drain contact structure 66 and the second backside source/drain contact structure 68 can be formed by filling the first source/drain contact opening 62 and extended second source/drain contact opening 64E, respectively, with a contact conductor material as defined above, and then performing a planarization process to remove the contact conductor material that is formed outside of the first source/drain contact opening 62 and extended second source/drain contact opening 64E.

A backside interconnect structure 70 is then formed on the backside ILD layer 52 and in direct physical contact with both the first backside source/drain contact structure 66 and the second backside source/drain contact structure 68. The backside interconnect structure 70 can include one or more interconnect dielectric material layers (including one of the dielectric materials mentioned above for the frontside ILD layer) that contain backside metal wires (the metal wires can be composed of any electrically conductive metal or electrically conductive metal alloy) embedded therein. The backside interconnect structure 70 can include “y” numbers of backside metal levels, wherein “y” is an integer starting from 1. The backside interconnect structure 70 can be formed utilizing techniques well known to those skilled in the art. In some embodiments, the backside metal wires in the backside interconnect structure 70 are composed of Cu.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a transistor located in a first device area and comprising a gate structure, a first source/drain region located on a first side of the gate structure and a second source/drain region located on a second side of the gate structure;
a frontside source/drain contact structure contacting a topmost surface of the first source/drain region;
a backside ballast resistor electrically contacting a bottommost surface of the second source/drain region; and
a backside source/drain contact structure in contact with the backside ballast resistor.

2. The semiconductor device of claim 1, further comprising a frontside back-end-of-the-line (BEOL) structure in contact with the frontside source/drain contact structure.

3. The semiconductor device of claim 1, further comprising a backside interconnect structure in contact with the backside source/drain contact structure.

4. The semiconductor device of claim 1, wherein the backside ballast resistor is in direct physical contact with the bottommost surface of the second source/drain region.

5. The semiconductor device of claim 1, further comprises a semiconductor layer located between the backside ballast resistor and the bottommost surface of the second source/drain region.

6. The semiconductor device of claim 1, wherein the transistor is a nanosheet transistor and the nanosheet transistor is located on a frontside of a bottom dielectric isolation layer.

7. The semiconductor device of claim 1, wherein the first source/drain region and the second source/drain region are of a first conductivity type, and the backside ballast resistor is of the first conductivity type.

8. The semiconductor device of claim 7, wherein the first conductivity type is n-type.

9. The semiconductor device of claim 7, wherein the first conductivity type is p-type.

10. The semiconductor device of claim 1, wherein the backside ballast resistor has an upper portion having a first width and a lower portion having a second width, wherein the second width is greater than the first width.

11. The semiconductor device of claim 10, wherein the backside source/drain contact structure has a third width that is less than the second width of the lower portion of the backside ballast resistor.

12. The semiconductor device of claim 1, further comprising a backside interlayer dielectric (ILD) layer embedding both the backside ballast resistor and the backside source/drain contact structure.

13. The semiconductor device of claim 1, further comprising a logic transistor located in a second device area that is adjacent to the first device area.

14. The semiconductor device of claim 13, wherein a source/drain region of the logic transistor is in electrical contact with a logic side backside source/drain contact structure.

15. The semiconductor device of claim 14, further comprising a backside interlayer dielectric (ILD) layer embedding each of the backside ballast resistor, the backside source/drain contact structure and the logic side backside source/drain contact structure.

16. The semiconductor device of claim 15, further comprising a backside interconnect structure in contact with the backside source/drain contact structure and the logic side backside source/drain contact structure.

17. The semiconductor device of claim 13, wherein the transistor and logic transistor are both nanosheet transistors, and each nanosheet transistor is located on a frontside of a bottom dielectric isolation layer.
